(19) United States
(12) Patent Application Publication
(10) Pub. No.: US 2026/0362614 A1
(43) Pub. Date: Nov. 12, 2026

(54) LOCKING AND RELEASING MECHANISM AND DISPLAY DEVICE

(71) Applicant: Unilumin Group Co., Ltd., Shenzhen, Guangdong (CN)

(72) Inventors: Wuquan LI, Shenzhen, Guangdong (CN); Tianpeng SUN, Shenzhen, Guangdong (CN); Zongwei ZHAO, Shenzhen, Guangdong (CN)

(73) Assignee: Unilumin Group Co., Ltd., Shenzhen, Guangdong (CN)

(21) Appl. No.: 19/491,456

(22) PCT Filed: Dec. 4, 2024
(86) PCT No.: PCT/CN2024/136858

§ 371 Date: Dec. 9, 2025

(30) Foreign Application Priority Data
Feb. 4, 2024 (CN) 202420274342.1

(51) Int. Cl. H05K 5/02; H05K 5/30

(52) U.S. Cl. CPC H05K 5/0221; H05K 5/30

(57) ABSTRACT

A locking-releasing mechanism (10) and a display device (100) are provided. The locking-releasing mechanism (10) includes a locking bar (11) and a locking hook (12), a locking groove (111) is formed at an outer surface of the locking bar (11), and the locking groove (111) extends along a circumferential direction of the locking bar (11). The locking hook (12) is configured to be movably disposed at a periphery of the locking bar (11) and configured to insert into and fit within the locking groove (111). An end of the locking hook (12) away from the locking bar (11) is used to be connected to a display panel (30). The locking bar (11) is rotatable about an axis thereof and has locked and released positions, and the locking groove (111) includes a first groove body (111a) and a second groove body (111b) connected in sequence along the circumferential direction of the locking bar (11). When the locking bar (11) is in the locked position, the first groove body (111a) is aligned with the locking hook (12), so that the locking hook (12) is secured within the first groove body (111a). When the locking bar (11) is in the released position, the second groove body (111b) is aligned with the locking hook (12), so that the locking hook (12) is released from the second groove body (111b). The locking-releasing mechanism (10) has a simpler structure and lower use cost.

### CROSS-REFERENCE TO RELATED APPLICATION

This application claims priority to Chinese Patent Application No. 202420274342.1 filed on Feb. 4, 2024, entitled “LOCKING-RELEASING MECHANISM AND DISPLAY DEVICE”, the content of which is incorporated herein by reference in its entirety.

### TECHNICAL FIELD

The present application relates to a field of display devices, and more particularly, to a locking-releasing mechanism and a display device.

### BACKGROUND

In the related art, a display device generally includes a display panel and a housing, and the housing can quickly secure the display panel by using an electronic lock to ensure data security. However, the structure of the electronic lock is relatively complex and the use cost thereof is relatively higher.

### SUMMARY

An object of the present disclosure is to provide a locking-releasing mechanism and a display device, to provide a locking-releasing mechanism having a simpler structure and a lower use cost.

To achieve the above object, an embodiment of the present disclosure provides a locking-releasing mechanism including:
a locking bar, where a locking groove is formed at an outer surface of the locking bar, and the locking groove extends along a circumferential direction of the locking bar; and
a locking hook, configured to be movably disposed at a periphery of the locking bar and configured to insert into and fit within the locking groove, where an end of the locking hook away from the locking bar is used to be connected to a display panel;
where the locking bar is rotatable about an axis of the locking bar and has a locked position and a released position, and the locking groove includes a first groove body and a second groove body connected in sequence along the circumferential direction of the locking bar;
under the condition that the locking bar is in the locked position, the first groove body is aligned with the locking hook, so that the locking hook is secured within the first groove body; and
under the condition that the locking bar is in the released position, the second groove body is aligned with the locking hook, so that the locking hook is released from the second groove body.

In an embodiment, the locking hook includes:
a connection part having a first end for being connected to the display panel and a second end movably disposed in the locking groove; and
a stopper connected to the second end of the connection part, where the stopper is configured to be inserted into the locking groove and movable in an extension direction of the locking groove to reciprocate movement between the first groove body and the second groove body;
where a cross-sectional area of the stopper is greater than a cross-sectional area of an opening of the first groove body, so that the stopper is stopped in the first groove body and the locking hook is locked in the first groove body;
the cross-sectional area of the stopper is less than the cross-sectional area of an opening of the second groove body, so that the stopper is disengaged from the second groove body and the locking hook is released from the second groove body.

In an embodiment, the locking bar is provided with a plurality of locking grooves, the plurality of locking grooves are arranged in sequence to be spaced apart from each other along a length direction of the locking bar; and
the locking hook is disposed to be plural so that a plurality of locking hooks are provided, and the plurality of locking hooks is provided corresponding one-to-one with the plurality of locking grooves.

In an embodiment, the locking-releasing mechanism further includes a rotating member provided at an end of the locking bar for driving the locking bar to rotate so that the locking bar is switched between the locked position and the released position.

In an embodiment, an insertion hole is provided at an end of the locking bar facing the rotating member, and an insertion block is provided at an end of the rotating member facing the locking bar, and the insertion block inserts into and fits within the insertion hole.

In an embodiment, a first fixing hole for communicating with the insertion hole is provided at an outer side wall of the locking bar, a second fixing hole is provided at an outer side wall of the insertion block, and the first fixing hole and the second fixing hole are aligned with each other in a radial direction of the locking bar; and
the locking-releasing mechanism further includes a positioning member for sequentially passing through the first fixing hole and the second fixing hole.

In an embodiment, the locking-releasing mechanism further includes a connection member, where opposite ends of the connection member are respectively detachably connected to ends of the two locking bars so that one of the two locking bars drives other one of the two locking bars to rotate through the connection member.

In an embodiment, a restriction hole is further provided at an outer side wall of the locking bar and extends along the circumferential direction of the locking bar; and/or
the locking-releasing mechanism further includes a bearing housing having a shaft hole therein, where the locking bar is rotatably disposed within the shaft hole.

An embodiment of the present disclosure further provides a display device including the locking-releasing mechanism according to any one of the above embodiments, the locking-releasing mechanism including:
a locking bar, where a locking groove is formed at an outer surface of the locking bar, and the locking groove extends along a circumferential direction of the locking bar; and
a locking hook, configured to be movably disposed at a periphery of the locking bar and configured to insert into and fit within the locking groove, where an end of the locking hook away from the locking bar is used to be connected to a display panel;
where the locking bar is rotatable about an axis of the locking bar and has a locked position and a released position, and the locking groove includes a first groove body and a second groove body connected in sequence along the circumferential direction of the locking bar;
under the condition that the locking bar is in the locked position, the first groove body is aligned with the locking hook, so that the locking hook is secured within the first groove body; and
under the condition that the locking bar is in the released position, the second groove body is aligned with the locking hook, so that the locking hook is released from the second groove body.

In an embodiment, the display device includes:
a housing, where an accommodation space having an opening at a side of the accommodation space is formed in the housing;
a display panel configured to cover the opening; and
the locking-releasing mechanism provided in the housing and connected to the display panel, to lock the display panel to the opening.

According to an embodiment of the present disclosure, the locking-releasing mechanism includes a locking bar and a locking hook, where a locking groove is formed at an outer surface of the locking bar, and the locking groove extends along the circumferential direction of the locking bar and includes a first groove body and a second groove body sequentially connected. The locking hook is movably disposed at the periphery of the locking bar for connecting the display panel. When the locking bar is rotatable about an axis of the locking bar, the locking groove may be moved relative to the locking hook to move the first groove body or the second groove body of the locking groove to a position aligned with the locking hook, respectively. When the first groove body is moved to a position facing the locking hook, the locking hook may be locked in the first groove body, and in turn, the display panel may be locked; When the second groove body is moved to a position facing the locking hook, the locking hook may be disengaged from the second groove body, and in turn the display panel may be released. In this way, by rotating the locking bar, the locking and releasing fit between the locking hook and the lock hole may be realized, thereby enabling the locking and releasing of the display panel. In addition, the locking-releasing mechanism including the locking bar and the locking hook has a relatively simpler structure, and it is advantageous to reduce the use cost of the locking-releasing mechanism.

### BRIEF DESCRIPTION OF THE DRAWINGS

In order that embodiments of the present disclosure or the technical solution in the prior art may be described more clearly, reference will now be made to the accompanying drawings provided for the description of the embodiments or the prior art, and it will be apparent that the accompanying drawings in the description below are merely some of the embodiments of the present disclosure, and that other drawings may be made to those skilled in the art without involving any inventive effort from the structures shown in the accompanying drawings.

FIG. 1 is a diagram of a display device according to some embodiments of the present disclosure;

FIG. 2 is a partial diagram of the display device of FIG. 1;

FIG. 3 is a sectional diagram of the display device of FIG. 1;

FIG. 4 is an enlarged diagram of a portion A in FIG. 3;

FIG. 5 is a partially enlarged diagram of the display device of FIG. 1;

FIG. 6 is a partially enlarged diagram of the display device of FIG. 5 in another state thereof;

FIG. 7 is a partial explosion diagram of the display device of FIG. 5;

FIG. 8 is another partial diagram of the display device of FIG. 1;

FIG. 9 is a partial explosion diagram of the display device of FIG. 8.

### LIST OF REFERENCE SIGNS

100. display device;
10. Locking-Releasing Mechanism; 11. Locking Bar; 111. Locking Groove; 111a, First Groove Body; 111b, Second Groove Body; 112, Insertion Hole; 113. First Fixing Hole; 114.
Restriction Hole; 12. Locking Hook; 121. Connection Part; 122, Stopper; 13. Rotating Member; 131. Insertion Block; 132. Second Fixing Hole; 14. Positioning Member; 15. Connection Member; 16. Bearing Housing; 161. Shaft Hole; 20. Housing; 30. Display panel.

### DETAILED DESCRIPTION

In the following, the technical solution in the embodiments of the present disclosure will be clearly and completely described in connection with the accompanying drawings of the embodiments of the present disclosure, and it will be apparent that the described embodiments are only a part of the embodiments of the present disclosure and not all of the embodiments. Based on the embodiments in the present disclosure, all other embodiments obtained by a person of ordinary skill in the art without involving any inventive effort are within the scope of the present disclosure.

It should be noted that all directional indications, such as up, down, left, right, front, back, or the like, in the embodiments of the present disclosure are only intended to explain the relative positional relationships, movements, and other aspects between respective components in a particular posture (as shown in the drawings). If the particular posture changes, the directional indicators will change accordingly.

In the description of the present disclosure, it should be noted that the terms “connection” and “fixing” should be understood in a broad sense, unless otherwise clearly defined. For example, it can be referred to be a fixed connection, a detachable connection, or an integrated connection; it can be referred to be a mechanical connection or an electrical connection; it can be referred to be directly connection or indirectly connection through an intermediary, it can also be referred to be the connection between two elements or the interaction between two elements. A person skilled in the art can understand the specific meanings of the above terms in the present disclosure according to specific situations.

In addition, the descriptions involving terms such as “first”, “second”, and the like in the present disclosure are for illustrative purposes only and are not to be construed as indicating or imposing a relative importance or implicitly indicating the number of technical features indicated. Thus, a feature that is limited by “first”, “second” may expressly or implicitly include at least one of the features. In addition, technical solutions from the various embodiments may be combined with each other. However, such a combination must be based on what can be achieved by a person of ordinary skill in the art. When the combination of the technical solutions results in mutual contradiction or is impossible to implement, it shall be considered that such a combination does not exist and is not within the scope claimed by the present disclosure.

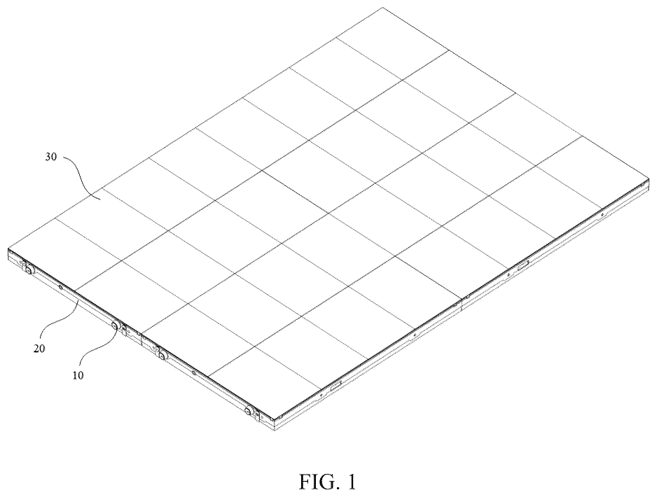

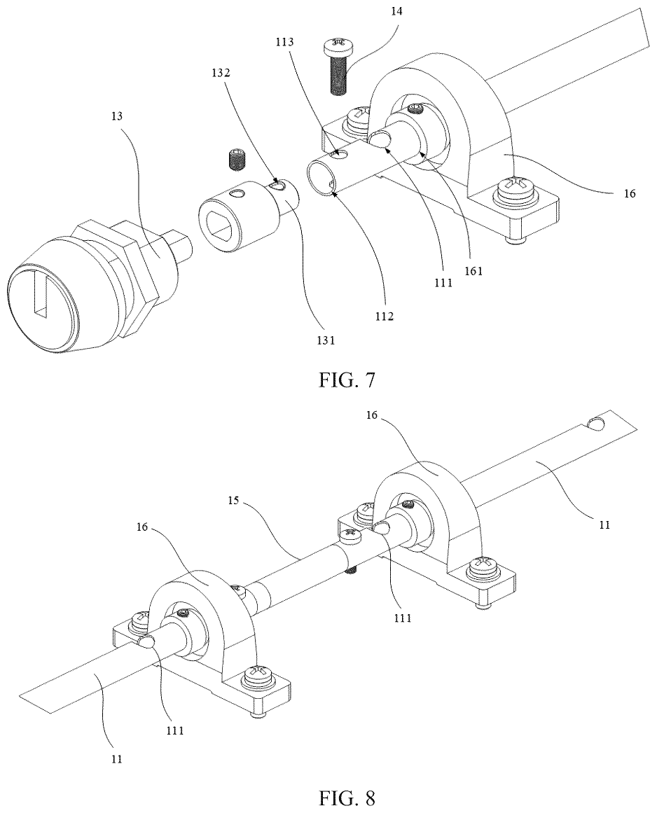

The objects, functional features, and advantages of the present disclosure will be further described with reference to FIGS. 1 to 9, in conjunction with the embodiments.

Some embodiments of the present disclosure provide a locking-releasing mechanism 10.

Referring to FIGS. 1-9, in the locking-releasing mechanism 10 according to some embodiments of the present disclosure, the locking-releasing mechanism 10 includes:
a locking bar 11, where a locking groove 111 is formed at an outer surface (i.e., outer side wall) of the locking bar 11 and the locking groove 111 extends along a circumferential direction of the locking bar 11; and
a locking hook 12, configured to be movably disposed at the periphery of the locking bar 11 and configured to insert into and fit within the locking groove 111, an end of the locking hook 12 away from the locking bar 11 is used to be connected to the display panel 30.

The locking bar 11 is rotatable about its axis and has a locked position and a released position, and the locking groove 111 includes a first groove body 111a and a second groove body 111b connected in sequence along the circumferential direction of the locking bar 11.

Under the condition that the locking bar 11 is in the locked position, the first groove body 111a is aligned with the locking hook 12, so that the locking hook 12 is secured within the first groove body 111a.

Under the condition that the locking bar 11 is in the released position, the second groove body 111b is aligned with the locking hook 12, so that the locking hook 12 is released from the second groove body 111b.

In an embodiment, the locking-releasing mechanism 10 includes the locking bar 11 and the locking hook 12, where the locking hook 12 has an end for connecting the display panel 30, and the other end for engaging with the locking groove 111 of the locking bar 11 in a locking-releasing way, allowing the display panel 30 to be securely locked and easily released. In an embodiment, the locking groove 111 is provided at the outer surface of the locking bar 11 and the locking groove 111 extends along a circumferential direction of the locking bar 11 and includes the first groove body 111a and the second groove body 111b connected in sequence. The locking hook 12 is movably provided on the periphery of the locking bar 11 to be connected to the display panel 30. When the locking bar 11 rotates about its axial direction, the locking groove 111 may be moved relative to the locking hook 12, so as to move the first groove body 111a or the second groove body 111b of the locking groove 111 to positions aligned with the locking hook 12, respectively. Under the condition that the first groove body 111a is moved to the position facing the locking hook 12, the locking hook 12 may be locked in the first groove body 111a, and then the display panel 30 may be locked. Under the condition that the second groove body 111b is moved to the position facing the locking hook 12, the locking hook 12 may be disengaged from the second groove body 111b, and in turn, the display panel 30 may be released.

It should be noted that, in the related art, the display device 100 generally includes a display panel 30 and a housing 20. The housing 20 can quickly secure the display panel 30 by using an electronic lock to ensure data security, thereby ensuring data security. However, the structure of the electronic lock is relatively complex and the use cost thereof is relatively higher.

Therefore, it will be appreciated that the locking-releasing mechanism according to an embodiment of the present disclosure, the locking and releasing for the display panel 30 are achieved through the locking-releasing engagement between the locking bar 11 and the locking hook 12. That is, the locking hook 12 may be locked in or released from the locking groove 111 of the locking bar 11 by rotating the locking bar 11, thereby enabling the locking and releasing of the display panel 30. In addition, the locking-releasing mechanism including the locking bar 11 and the locking hook 12 has a relatively simpler structure, and it is advantageous to reduce the use cost of the locking-releasing mechanism 10.

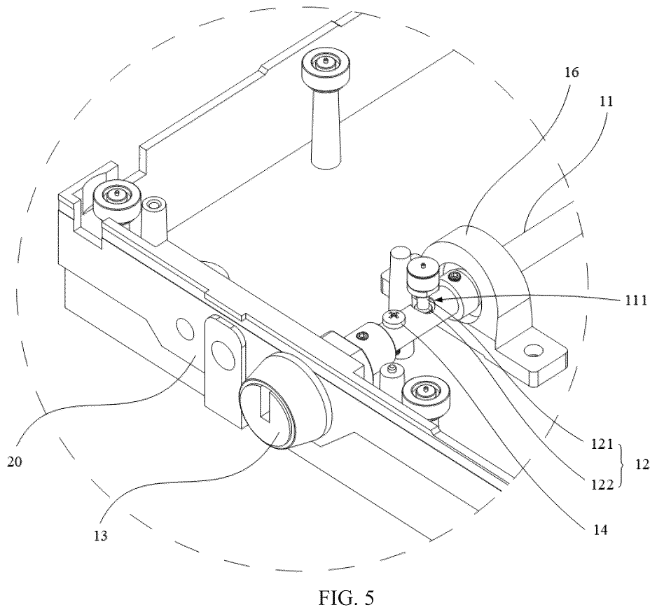

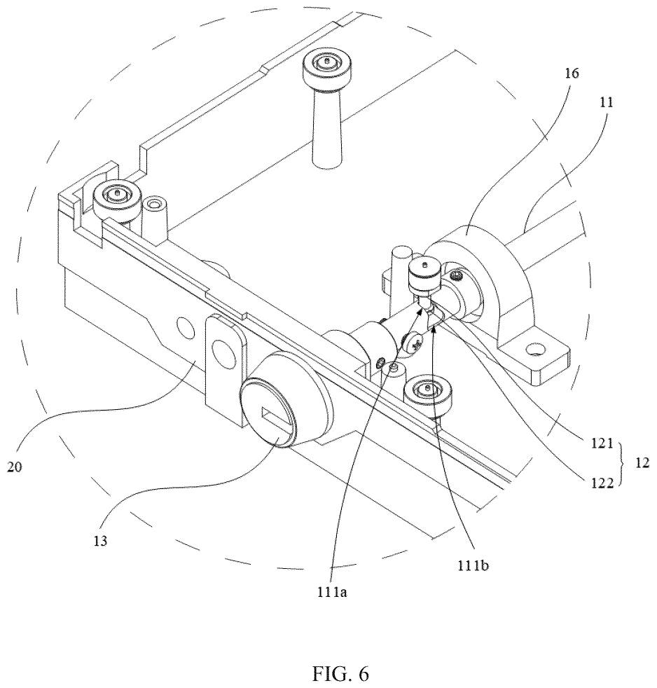

Referring to FIG. 5 or FIG. 6, in the locking-releasing mechanism 10 according to some embodiments of the present disclosure, the locking hook 12 includes:
a connection part 121, having a first end for being connected to the display panel 30 and a second end movably disposed in the locking groove 111; and
a stopper 122 connected to an end of the connection part 121 away from the display panel 30, the stopper 122 configured to be inserted into the locking groove 111 and movable in an extension direction of the locking groove 111 to reciprocate movement between the first groove body 111a and the second groove body 111b.

A cross-sectional area of the stopper 122 is greater than a cross-sectional area of an opening of the first groove body 111a, so that the stopper 122 may be stopped in the first groove body 111a and thus the locking hook 12 is locked in the first groove body 111a;

The cross-sectional area of the stopper 122 is less than the cross-sectional area of an opening of the second groove body 111b, so that the stopper 122 may be disengaged from the second groove body 111b, and thus the locking hook 12 is released from the second groove body 111b.

In an embodiment, the outer surface of the locking bar 11 is provided with the locking groove 111 including the first groove body 111a and the second groove body 111b sequentially connected with each other along the circumferential direction of the locking bar 11. The cross-sectional area of the opening of the first groove body 111a is less than the cross-sectional area of the second groove body 111b. The locking hook 12 includes the connection part 121 and the stopper 122. The cross-sectional area of the connection part 121 is not greater than the cross-sectional area of the first groove body 111a, so that the connection part 121 may freely enter or disengage from the locking groove 111, that is, the connection part 121 is movably provided relative to the locking groove 111. The cross-sectional area of the stopper 122 is greater than the cross-sectional area of the first groove body 111a and not greater than the cross-sectional area of the second groove body 111b, so that the stopper 122 may freely enter or disengage from only the second groove body 111b, that is, the stopper 122 may be locked in the first groove body 111a when the stopper 122 is aligned with the first groove body 111a, and may be disengaged from the first groove body 111a when the stopper 122 is aligned with the second groove body 111b.

Referring to FIG. 3, in the locking-releasing mechanism 10 according to some embodiments of the present disclosure, the locking groove 111 is disposed to be plural so that a plurality of locking grooves 111 are provided, the plurality of locking grooves 111 are arranged in sequence to be spaced apart from each other along a length direction of the locking bar 11.

The locking hook 12 is disposed to be plural. That is, a plurality of locking hooks 12 are provided. The locking hooks 12 are provided corresponding one-to-one with the locking grooves 111.

In some embodiments of the present disclosure, a plurality of locking grooves 111 are provided at the outer surface of the locking bar 11, and the plurality of locking grooves 111 are arranged in sequence to be spaced apart from each other along a length direction of the locking bar 11, and each of the locking grooves 111 may be used for the locking-releasing engagement with the locking hook 12. In this way, each locking hook 12 may be connected to the display panel 30 so that one locking bar 11 may lock and release a plurality of display panels 30 through the plurality of locking hooks 12. The technical solution of the present disclosure is not limited thereto, and in some embodiments, the plurality of locking hooks 12 and one display panel 30 may be connected so as to improve the locking stability of the display panel 30.

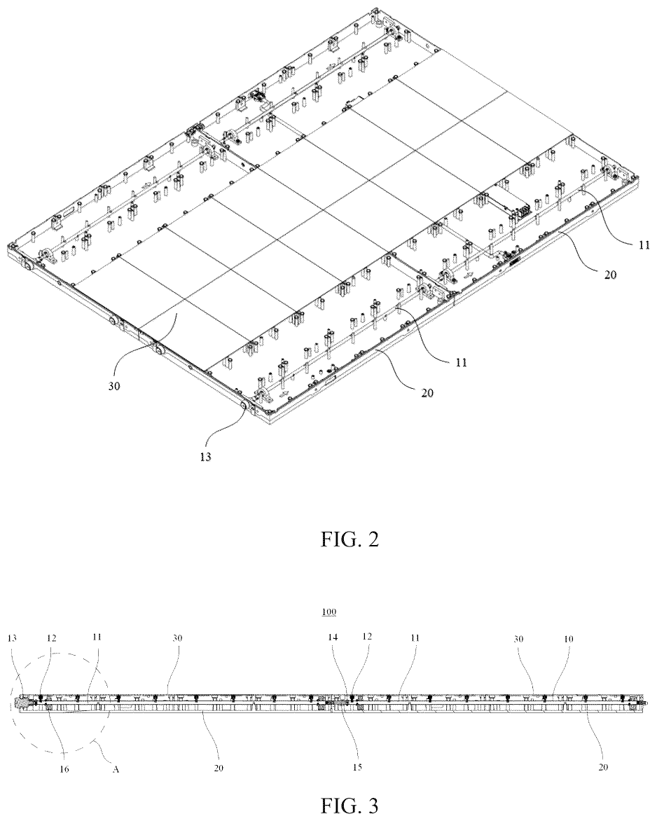

Referring to FIGS. 2 to 7, in the locking-releasing mechanism 10 according to some embodiments of the present disclosure, the locking-releasing mechanism 10 further includes a rotating member 13 provided at an end of the locking bar 11 for driving the locking bar 11 to rotate so that the locking bar 11 is switched between the locked position and the released position.

In an embodiment, the rotating member 13 is provided at the end of the locking bar 11 for driving the locking bar 11 to rotate about the axial direction of the locking bar 11, so as to switch the locking bar 11 between the locked position and the released position, and then the locking hook 12 and the display panel 30 may be locked into or released from the locking bar 11. The rotating member 13 may be driven by manual rotation, or may be provided as a power driving mechanism, which is not limited herein.

Referring to FIGS. 5 to 7, in the locking-releasing mechanism 10 according to some embodiments of the present disclosure, an insertion hole 112 is provided at an end of the locking bar 11 facing the rotating member 13, and an insertion block 131 is provided at an end of the rotating member 13 facing the locking bar 11, and the insertion block 131 inserts into and fits within the insertion hole 112.

In an embodiment, each of the insertion hole 112 and the insert block 131 extends along the axial direction of the locking bar 11. By enabling the insert block 131 to insert into and fit within the insertion hole 112, the locking bar 11 may be easily aligned with the rotating member 13 in the axial direction of the locking hook 12.

Referring to FIGS. 5 to 7, in the locking-releasing mechanism 10 according to some embodiments of the present disclosure, a first fixing hole 113 for communicating with the insertion hole 112 is provided at an outer side wall of the locking bar 11, a second fixing hole 132 is provided at an outer side wall of the insertion block 13, and the first fixing hole 113 and the second fixing hole 132 are aligned with each other in a radial direction of the locking bar 11.

The locking-releasing mechanism 10 further includes a positioning member 14 for sequentially passing through the first fixing hole 113 and the second fixing hole 132.

With this arrangement, the positioning member 14 may be fixedly engaged with the locking rod 11 and the insertion block 131 of the rotating member 13 by sequentially passing the positioning member 14 through the first fixing hole 113 and the second fixing hole 132, respectively, and thus the restricting and the fixing of the locking rod 11 and the rotating member 13 in the radial direction of the locking rod 11 may be realized, thereby improving the positional stability between the locking rod 11 and the rotating member 13.

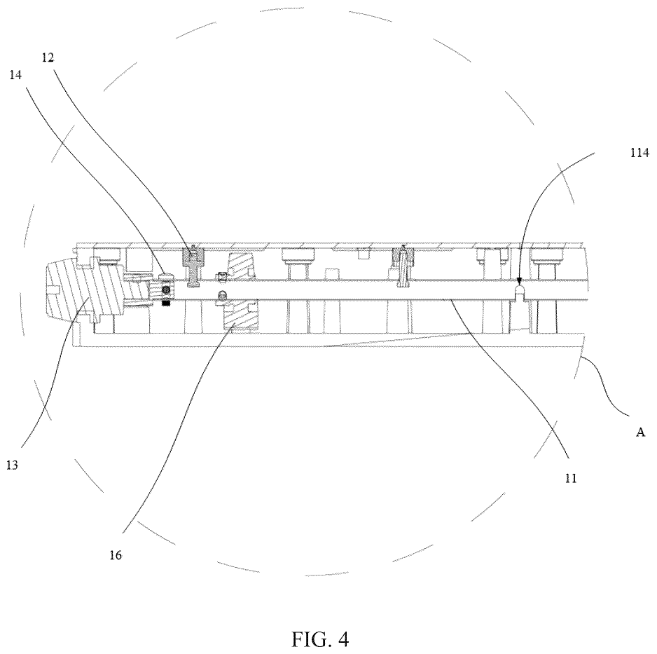

Referring to FIG. 4, in the locking-releasing mechanism 10 according to some embodiments of the present disclosure, a restriction hole 114 is further provided at the outer side wall of the locking bar 11 and extends along the circumferential direction of the locking bar 11.

In an embodiment, a restriction element outside the locking bar 11 inserts into and fits within the restriction hole 114 to improve the mounting stability of the locking bar 11. Further, the restriction hole 114 is provided to extend along the circumferential direction of the locking bar 11, so that when the locking bar 11 rotates about the axial direction thereof, the restriction hole 114 may be moved relative to the restriction element outside the locking bar 11. That is, the restriction element does not interfere with the rotational movement of the locking bar 11 while restricting the locking bar 11, without affecting the locking-releasing function of the locking-releasing mechanism 10.

In the locking-releasing mechanism 10 according to some embodiments of the present disclosure, the locking-releasing mechanism 10 further includes a bearing housing 16 having a shaft hole 161 therein. The locking bar 11 is rotatably disposed within the shaft hole 161.

In an embodiment, by providing the bearing housing 16, the radial movement of the locking bar 11 may be restricted, and the position stability of the locking bar 11 may be improved. In an embodiment, the locking-releasing mechanism 10 may further be provided with a shaft sleeve enclosing the periphery of the locking bar 11 to facilitate reduction of rotational friction experienced by the locking bar 11 and facilitate smooth rotational switching between the locked position and the released position of the locking bar 11.

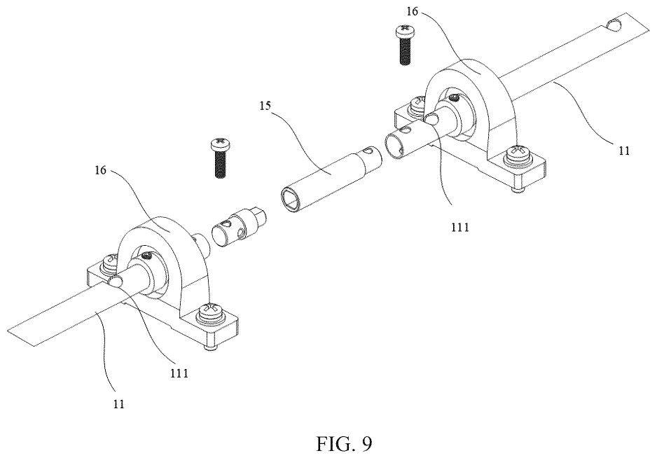

Referring to FIGS. 8 and 9, in the locking-releasing mechanism 10 according to some embodiments of the present disclosure, the locking-releasing mechanism 10 further includes a connection member 15. Opposite ends of the connection member 15 are respectively detachably connected to the ends of the two locking bars 11 so that one of the two locking bars 11 may drive the other one of the two locking bars 11 to rotate through the connection member 15.

In an embodiment, by detachably connecting the opposite ends of the connection member 15 to the ends of the locking bars 11, respectively, the motion transmission may be realized, so that adjacent ones of the locking bars 11 may be rotated synchronously by the connection member 15.

Some embodiments of the present disclosure further provide a display device 100 including the locking-releasing mechanism 10 described in any one of the foregoing embodiments. The configuration of the locking-releasing mechanism 10 may refer to any one of the foregoing embodiments. Since the display device 100 according to some embodiments of the present disclosure is applicable to all of the above-described embodiments, and thus has all of the beneficial effects brought about by the above-described embodiments, which will not be repeated here.

Referring to FIGS. 1 and 2, with reference to the locking-releasing mechanism 10 according to some embodiments of the present disclosure, the display device 100 includes:
a housing 20, where an accommodation space having an opening at a side of the accommodation space is formed in the housing 20;
a display panel 30 configured to cover the opening; and
a locking-releasing mechanism 10, provided in the housing 20 and connected to the display panel 30, to lock the display panel 30 to the opening.

In an embodiment, the display device 100 includes the housing 20, the display panel 30, and the locking-releasing mechanism 10, and an end portion of the locking-releasing mechanism 10 may extend from the inside of the housing 20 to the outer side of the housing 20 and protrude from the housing 20, to expose the rotating member 13 of the locking-releasing mechanism 10 outside the housing 20, thereby facilitating rotation of the locking-releasing mechanism 10 by the user through the rotating member 13.

In some embodiments, through-holes are formed at opposite ends of the housing 20, respectively, and the opposite ends of the locking-releasing mechanism 10 are exposed through the through-holes, respectively. In this way, the position stability of the locking-releasing mechanism 10 may be improved by restricting the locking-releasing mechanism 10 through the through-holes. In addition, a portion of the locking-releasing mechanism 10 may be exposed to the outside of the housing 20 to facilitate connection and engagement with an external mechanism. For example, in some embodiments, the display device 100 includes a plurality of housings 20 arranged side by side and configured to be spliced with each other, and each locking-releasing mechanism 10 is disposed in each housing 20. In this way, the locking-releasing mechanisms 10 respectively in two adjacent ones of the housings 20 may be connected through the connection member 15 in the foregoing embodiments. This enables motion transmission between the locking-releasing mechanisms 10 in the two adjacent ones of the housings 20, to synchronously lock and release the plurality of display panels 30, thereby improving the operational convenience for the display panels 30 in the same row in the display device 100.

The foregoing description is merely some embodiments of the present disclosure, and thus does not limit the present disclosure, and equivalent structural modifications made by the description and drawings of the present disclosure, or any direct/indirect applications thereof in other related technical fields, are included within the scope of the present disclosure.

1. A locking-releasing mechanism comprising:
a locking bar, wherein a locking groove is formed at an outer side wall of the locking bar, and the locking groove extends along a circumferential direction of the locking bar; and
a locking hook, configured to be movably disposed at a periphery of the locking bar and configured to insert into and fit within the locking groove, wherein an end of the locking hook away from the locking bar is used to be connected to a light panel;
wherein the locking bar is rotatable about an axis of the locking bar and has a locked position and a released position, and the locking groove comprises a first groove body and a second groove body connected in sequence along the circumferential direction of the locking bar;
under the condition that the locking bar is in the locked position, the first groove body is aligned with the locking hook, so that the locking hook is secured within the first groove body; and
under the condition that the locking bar is in the released position, the second groove body is aligned with the locking hook, so that the locking hook is released from the second groove body.

2. The locking-releasing mechanism of claim 1, wherein the locking hook comprises:
a connection part having an end for being connected to the display panel and other end movably disposed in the locking groove; and
a stopper connected to an end of the connection part away from the display panel, wherein the stopper is configured to be inserted into the locking groove and movable in an extension direction of the locking groove to reciprocate movement between the first groove body and the second groove body;
wherein a cross-sectional area of the stopper is greater than a cross-sectional area of an opening of the first groove body, so that the stopper is stopped in the first groove body and the locking hook is locked in the first groove body; and
the cross-sectional area of the stopper is less than the cross-sectional area of an opening of the second groove body, so that the stopper is disengaged from the second groove body and the locking hook is released from the second groove body.

3. The locking-releasing mechanism of claim 2, wherein the locking bar is provided with a plurality of locking grooves, the plurality of locking grooves are arranged in sequence to be spaced apart from each other along a length direction of the locking bar; and
the locking hook is disposed to be plural so that a plurality of locking hooks are provided, and the plurality of locking hooks is provided corresponding one-to-one with the plurality of locking grooves.

4. The locking-releasing mechanism of claim 1, further comprising: a rotating member provided at an end of the locking bar for driving the locking bar to rotate so that the locking bar is switched between the locked position and the released position.

5. The locking-releasing mechanism of claim 4, wherein an insertion hole is provided at an end of the locking bar facing the rotating member, and an insertion block is provided at an end of the rotating member facing the locking bar, and the insertion block inserts into and fits within the insertion hole.

6. The locking-releasing mechanism of claim 5, wherein a first fixing hole for communicating with the insertion hole is provided at the outer side wall of the locking bar, a second fixing hole is provided at an outer side wall of the insertion block, and the first fixing hole and the second fixing hole are aligned with each other in a radial direction of the locking bar; and
the locking-releasing mechanism further comprises a positioning member for sequentially passing through the first fixing hole and the second fixing hole.

7. The locking-releasing mechanism of claim 1, wherein a restriction hole is further provided at the outer side wall of the locking bar and extends along the circumferential direction of the locking bar.

8. The locking-releasing mechanism of claim 1, further comprising: a bearing housing having a shaft hole therein, wherein the locking bar is rotatably disposed within the shaft hole.

9. The locking-releasing mechanism of claim 1, further comprising a connection member, wherein the locking bar is disposed to be plural so that a plurality of locking hooks are provided, opposite ends of the connection member are respectively detachably connected to ends of two ones of the plurality of locking bars so that one of the two ones of the plurality of locking bars drives other one of the two ones of the plurality of locking bars to rotate through the connection member.

10. A display device comprising a locking-releasing mechanism of claim 1.

11. The display device of claim 10, wherein the display device comprises:
a housing, wherein an accommodation space having an opening at a side of the accommodation space is formed in the housing;
a display panel configured to cover the opening; and
the locking-releasing mechanism provided in the housing and connected to the display panel, to lock the display panel to the opening.

12. The display device of claim 10, wherein the display device comprises:
a housing;
a display panel; and
the locking-releasing mechanism, wherein an end portion of the locking-releasing mechanism extends from an inside of the housing to an outer side of the housing and protrudes from the housing, to expose the rotating member of the locking-releasing mechanism outside the housing.

13. The display device of claim 10, wherein the locking hook comprises:
a connection part having a first end for being connected to the display panel and a second end movably disposed in the locking groove; and
a stopper connected to the second end of the connection part, wherein the stopper is configured to be inserted into the locking groove and movable in an extension direction of the locking groove to reciprocate movement between the first groove body and the second groove body;
wherein a cross-sectional area of the stopper is greater than a cross-sectional area of an opening of the first groove body, so that the stopper is stopped in the first groove body and the locking hook is locked in the first groove body; and
the cross-sectional area of the stopper is less than the cross-sectional area of an opening of the second groove body, so that the stopper is disengaged from the second groove body and the locking hook is released from the second groove body.

14. The display device of claim 13, wherein the locking bar is provided with a plurality of locking grooves, the plurality of locking grooves are arranged in sequence to be spaced apart from each other along a length direction of the locking bar, and
the locking hook is disposed to be plural so that a plurality of locking hooks are provided, and the plurality of locking hooks is provided corresponding one-to-one with the plurality of locking grooves.

15. The display device of claim 10, wherein the locking-releasing mechanism further comprises: a rotating member provided at an end of the locking bar for driving the locking bar to rotate so that the locking bar is switched between the locked position and the released position.

16. The display device of claim 15, wherein an insertion hole is provided at an end of the locking bar facing the rotating member, and an insertion block is provided at an end of the rotating member facing the locking bar, and the insertion block inserts into and fits within the insertion hole.

17. The display device of claim 16, wherein a first fixing hole for communicating with the insertion hole is provided at the outer side wall of the locking bar, a second fixing hole is provided at an outer side wall of the insertion block, and the first fixing hole and the second fixing hole are aligned with each other in a radial direction of the locking bar;
the locking-releasing mechanism further comprises a positioning member for sequentially passing through the first fixing hole and the second fixing hole.

18. The display device of claim 10, wherein a restriction hole is further provided at the outer side wall of the locking bar and extends along the circumferential direction of the locking bar.
